(19) United States
(12) Patent Application Publication
(10) Pub. No.: US 2005/0126620 A1
(43) Pub. Date: Jun. 16, 2005

(54) Photoelectric converting device and its production method

(75) Inventors: Ichiroh Yamasaki, Kitakatsuragi-gun (JP); Tohru Nunoi, Nara-shi (JP)

Correspondence Address: NIXON & VANDERHYE, PC, 1100 N GLEBE ROAD, 8TH FLOOR, ARLINGTON, VA, 22201-4714, US

(73) Assignee: Sharp Kabushiki Kaisha, Osaka (JP)

(21) Appl. No.: 10/506,895

(22) PCT Filed: Mar. 3, 2003
(86) PCT No.: PCT/JP03/02408

(30) Foreign Application Priority Data
Mar. 6, 2002 (JP) 2002-60647

(51) Int. Cl. H01L 31/00

(52) U.S. Cl. 136/246; 136/256

(57) ABSTRACT

In a photoelectric conversion device using a first conductivity type semiconductor substrate having convex and concave portions formed on its surface, the device being characterized in that it comprises at least, a second conductivity type semiconductor layer formed on the surface of the first conductivity type semiconductor substrate, a front electrode connected to the second conductivity type semiconductor layer, and a rear electrode formed on the rear surface of the first conductivity type semiconductor substrate, the second conductivity type semiconductor layer being in contact with the front electrode and becoming thinner as it goes farther from the contacted area.

### TECHNICAL FIELD

The present invention relates to a photoelectric conversion device and a manufacturing method therefor, and more specifically, to a photoelectric conversion device wherein the thickness of a diffusion layer on a light-receiving side of the device is changed, thereby to improve photoelectric conversion efficiency of a silicon solar cell or the like and a manufacturing method therefor.

### BACKGROUND ART

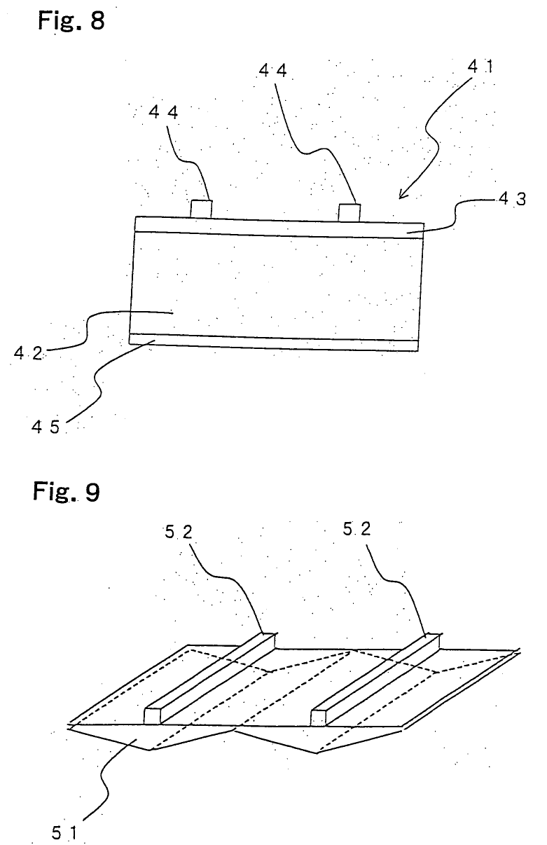

As illustrated in FIG. 8, conventional photoelectric conversion devices are composed of, for example, an N type semiconductor layer 43 formed on one surface of a P type semiconductor substrate 42 as a substrate, collecting electrodes 44 formed thereon, and a rear electrode 45 formed on a rear surface of the P type semiconductor substrate 42.

Electric current generated by radiating sunlight onto the surface of the N type semiconductor layer 43 flows in the N type semiconductor layer 43, and is then taken out from the collecting electrodes 44.

In general, the sensitivity of the N type semiconductor layer 43 to short wavelengths of light is better as the thickness of the layer is smaller. Consequently, the electric current generated therefrom becomes larger, but the sheet resistance thereof becomes larger. Therefore, as the N type semiconductor layer 43 becomes thinner, the electric power taken out from the collecting electrodes 44 becomes lower.

To solve this problem fact, the thickness of the N type semiconductor layer and the arrangement of the collecting electrodes are optimized so that the photoelectric conversion efficiency increases. For example, contrivance is made to make the N type semiconductor layer as thin as possible and narrow mutual intervals between the collecting electrodes appropriately.

However, if the N type semiconductor layer is made too thin, the sheet resistance increases. When the mutual intervals between the collecting electrodes are narrowed, the effectual light-receiving area of the N type semiconductor layer decreases, resulting in a problem that optically-generated current decreases.

Thus, there is suggested a photoelectric conversion device wherein collecting-electrode-formed portions of an N type semiconductor layer are made thick and the other portions are made thin (for example, patent document 1).

As another example, there is suggested a photoelectric conversion device as illustrated in FIG. 9, wherein an N type semiconductor layer 51 is made thin at central portions between each collecting electrode 52, and the layer 51 is gradually made thicker toward the collecting electrodes 52 (for example, patent document 2). According to this photoelectric conversion device, the sensitivity thereof to short wavelengths can be improved at portions where the N type semiconductor layer 51 is thin. Furthermore, the series resistance loss thereof can be made small since carriers generated in the thin portions moves toward the collecting electrodes 52 through the N type semiconductor layer 51 which gradually becomes thicker.

However, in the photoelectric conversion device wherein the collecting-electrode-formed portions of an N type semiconductor layer are made thick and the other portions are made thin, it is necessary to form a mask pattern and conduct impurity-diffusion two times, so that the N type semiconductor layer is formed.

In the photoelectric conversion device illustrated in FIG. 9, it is necessary to form the N type semiconductor layer by forming plural mask patterns and then performing multiply diffusion or ion implantation by means of thermal diffusion or performing multiply diffusion by means of laser.

Accordingly, either one of the photoelectric conversion devices has problems that the production process is complicated thereby costs increase.

Patent Document 1: JP-A-62-123778

Patent Document 2: JP-A-4-356972

The present invention has been made in light of the above-mentioned problems. An object thereof is to provide a photoelectric conversion device which can be produced by a simple production process, and a manufacturing method therefor.

### DISCLOSURE OF THE INVENTION

According to the invention, provided is a photoelectric conversion device using a first conductivity type semiconductor substrate having convex and concave portions formed on its surface, the device being characterized in that it comprises at least, a second conductivity type semiconductor layer formed on the surface of the first conductivity type semiconductor substrate, a front electrode connected to the second conductivity type semiconductor layer, and a rear electrode formed on the rear surface of the first conductivity type semiconductor substrate, the second conductivity type semiconductor layer being at its partial area contact with the front electrode and becoming thinner as it goes farther from the contacted area.

According to the invention, provided is a method for manufacturing a photoelectric conversion device comprising the steps (a) of forming a film serving as a barrier against impurity diffusion on a semiconductor substrate having convex and concave portions formed on its surface in such a manner that the film becomes thicker from the convex portion to the concave portion, and the steps (b) of implanting second conductivity type impurities into the semiconductor substrate through the film to form a second conductivity type semiconductor layer on the surface of the semiconductor substrate, and step (c) of forming a front electrode that is in contact with the convex portion which constitute a part of the semiconductor substrate surface.

According to the invention, provided is a method for manufacturing a photoelectric conversion device comprising the steps (a′) of forming a film containing second conductivity type impurities on a semiconductor substrate having convex and concave portions formed on its surface in such a manner that the film becomes thicker from the convex portion to the concave portion, and steps (b′) of implanting second conductivity type impurities into the semiconductor substrate from the film to form a second conductivity type semiconductor layer on the surface of the semiconductor substrate, and steps (c′) of forming a front electrode that is in contact with the concave portion which constitute a part of the semiconductor substrate surface.

### BEST MODES FOR CARRYING OUT THE INVENTION

The photoelectric conversion device of the present invention uses a first conductivity type semiconductor substrate having convex and concave portions formed on its surface, and comprises a second conductivity type semiconductor layer formed on the surface of the first conductivity type semiconductor substrate, a front electrode connected to the second conductivity type semiconductor layer, and a rear electrode formed on the rear surface of the first conductivity type semiconductor substrate.

The semiconductor substrate is not particularly limited, and may be any substrate that is usually used in photoelectric conversion devices. Examples of the semiconductor substrate include a semiconductor substrate made of a IV group element such as silicon or germanium; and a semiconductor substrate made of a compound such as GaAs or InGaAs. A substrate made of silicon is particularly preferable. The semiconductor substrate may be amorphous, monocrystalline, polycrystalline, microcrystalline, or a combination thereof.

The semiconductor substrate is doped with impurities of a first conductivity type (for example, an N type or a P type) to make the substrate conductive.

The kind of the impurities can be appropriately selected depending on the semiconductor material used. Examples of the N type impurities include phosphorus, arsenic, and antimony. Examples of the P type impurities include boron, aluminum, germanium, indium, and titanium. The impurity concentration is not particularly limited. It is suitable that the impurity concentration is adjusted so that the substrate has, for example, a resistivity of about 0.1 to 10 Ω·cm.

The thickness of the semiconductor substrate is not particularly limited, and is preferably set in such a manner that the semiconductor substrate can keep a suitable strength and give a high photoelectric conversion efficiency. The thickness may be, for example, from about 0.2 to 0.4 mm on average.

The semiconductor substrate has convex and concave portions on a surface thereof. The pattern of the convex and concave portions is not particularly limited, and may be, for example, a pattern in which the convex portions having the same size or different sizes are arranged at regular intervals or at random, or a pattern in which grooves are formed as concave portions. A pattern in which convex portions are arranged at regular intervals or a pattern in which grooves are continuously formed at a given pitch is particularly preferable in order to efficiently take out carriers generated in the under mentioned second conductivity type semiconductor layer, from the front electrodes. The pitch of the convex portion and the pitch of the concave portions are not particularly limited and are, for example, from about 1 to 3 mm, in view of the width of the under mentioned front electrodes. The difference of the elevation between the convex and concave portions is not particularly limited, and is, for example, from about 0.05 to 0.1 mm.

The semiconductor substrate having the convex and concave portions on a surface thereof can be formed, for example, by photolithography and etching. The semiconductor substrate can also be formed by growing a semiconductor layer on a plate having convex and concave portions, as described in Japanese unexamined patent publication 11-339016. By changing the pattern of the convex and concave portions of the plate, the pattern of the convex and concave portions of the semiconductor layer can be made into a desired form.

The second conductivity type semiconductor layer is formed on one surface of the semiconductor substrate, that is, on the surface of the first conductivity type semiconductor substrate. The second conductivity type semiconductor layer is doped with impurities of a second conductivity type (a P type or an N type). The impurity concentration is not particularly limited. It is appropriate to adjust the impurity concentration in such a manner that the layer has the surface concentration of about 1×10¹⁹ to 1×10²¹ cm⁻³ and the average sheet resistance of about 40 to 150 Ω/□. It is suitable that the film thickness of the second conductivity type semiconductor layer is about 0.3 to 0.6 μm at the thickest portions and is about 0.1 to 0.2 μm at the thinnest portions.

The following may be formed on the second conductivity type semiconductor layer: an antireflection film such as a silicon nitride film; a coating film or a protective film obtained by applying TG liquid (mixed liquid of tetra-i-propoxytitanium, an alcohol, and so on), from which titanium glass can be formed, or SG liquid (mixed liquid of ethyl silicate, an alcohol and so on), from which silicon glass can be formed. The film thickness of the antireflection film is, for example, about 60 to 110 nm, and the film thickness of the coating film is, for example, about 200 nm to 1 μm.

The material which constitutes the front electrodes is not particularly limited. Examples of the material include aluminum, silver, copper, aluminum/lithium alloy, magnesium/silver alloy, and indium.

The rear electrode is formed on the rear surface of the semiconductor substrate, and is preferably formed on the entire rear surface. The film thickness and the material of the rear electrode can be appropriately adjusted or selected in the same manner as the front electrodes.

In the case where the photoelectric conversion device of the present invention has the second conductivity type semiconductor layer that is thick at convex portions thereof and thin at concave portions thereof, the second conductivity type semiconductor layer becomes thinner as it goes farther from the under mentioned area where the layer and the front electrodes contact each other. In other words, it is preferred that the thickness of the second conductivity type semiconductor layer becomes thinner from the convex portions to the concave portions of the semiconductor substrate. In the semiconductor substrate in which grooves are continuously made, it is preferred that the thickness of the second conductivity type semiconductor layer is largest at the top of the convex portions in stripe form which are provided between the respective grooves and becomes evenly thinner from the top of the convex portions to the bottom of the grooves. In the semiconductor substrate in which the convex portions are arranged at regular intervals or in a lattice form, it is preferred that the thickness of the second conductivity type semiconductor layer is largest only at the top of the convex portions and becomes thinner almost radially from the top of the convex portions to the concave portions. The pitch of the convex portions and the pitch of the concave portions are not particularly limited and are, for example, about 1 to 3 mm in view of considering the width of the front electrodes. The difference of the elevation between the convex and concave portions is not particularly limited, and is, for example, about 0.05 to 0.1 mm.

In this case, the front electrodes are connected to a portion of the second conductivity type semiconductor layer. The portion where the front electrodes and the second conductivity type semiconductor layer contact each other is not particularly limited. For example, it is preferred that the front electrodes contact with the thickest portion of the second conductivity type semiconductor layer. For example, in the case where the grooves are continuously made in the semiconductor substrate, the electrode and the layer may contact each other at a linear top portion of the convex portions in stripe form which are provide between the respective grooves, or at contacted areas arranged at regular intervals on the top of the convex portions. In the case where the convex portions are arranged at regular intervals or in a lattice form, the front electrodes may contact with the semiconductor layer only at portions on the top of the convex portions. The shape of the area where the front electrodes and the second conductivity type semiconductor layer contact each other may be any shape. In view of the contact resistance and surface recombination, the contacted area as a whole is preferably about 0.1 to 3% (inclusive) relative to the surface of the substrate.

The shape of the front electrodes is not particularly limited. In the case where the convex portions are arranged at regular intervals or in a lattice form, it is preferable that the plurality of the front electrodes, are provided so that each electrode extend over a number of said convex portions. It is suitable that the front electrodes has a thickness of, for example, about 5 to 20 μm and a width of, for example, about 50 to 150 μm. The pitch between of the front electrodes is preferably even. This pitch is appropriately adjusted in accordance with the arrangement of the convex portions of the semiconductor substrate, and is, for example, about 1 to 3 mm.

According to a first embodiment of the manufacturing method of a photoelectric conversion device of the invention, a film serving as a barrier against impurity diffusion is first formed in step (a), on a first conductivity type semiconductor substrate having convex and concave portions on a surface thereof, so that the film becomes thicker from the convex portion to the concave portion.

The second conductivity type semiconductor layer may be formed either by doping the surface of the semiconductor substrate with second conductivity type impurities by means of gas-phase diffusion, solid-phase diffusion, ion implantation or the like, or by growing the second conductivity type semiconductor layer while doping the layer with second conductivity type impurities; and other methods.

The barrier film against impurity diffusion may be formed on the semiconductor substrate by applying an appropriate coating solution for forming the film by means of spin coating, dip coating, spray coating or some other coating onto the semiconductor substrate, and then drying the applied solution. In the case where the coating solution is applied onto the substrate surface having the convex and concave portions by spin coating, the solution remains easily in the concave portions. Therefore, the coating film can easily be formed so as to become continuously or gradually thicker from the convex portions to the concave portions of the semiconductor substrate.

Examples of the coating solution include TG liquid from which titanium glass can be made, and SG liquid from which silicon glass can be made. The film thickness of the coating film can be appropriately adjusted depending on the material of the coating film, the diffusing method and the kind of second conductivity type impurities, which will be described later. It is suitable that the film thickness is, for example, about 50 to 300 nm at the thickest portions and is, for example, about 0 to 50 nm at the thinnest portions.

In step (b), second conductivity type impurities are implanted into the resultant substrate through the previously-formed film, so as to form a second conductivity type semiconductor layer in the surface of the semiconductor substrate.

Since the second conductivity type impurities are implanted through the impurity-diffusion-barrier film which is formed previously on the semiconductor substrate, the impurities are less implanted as the thickness of the film becomes larger. For this reason, the second conductivity type semiconductor layer is formed thin. In other words, the second conductivity type semiconductor layer is formed in such a manner that the thickness of the layer is inclined to become thinner from the convex portions to the concave portions of the semiconductor substrate. The method for implanting the impurities is not particularly limited and may be any method that makes the introduction possible through the impurity-diffusion-barrier film. Examples of the method include gas-phase diffusion (thermal diffusion), solid-phase diffusion, and ion implantation. The gas-phase diffusion is particularly preferable since the process thereof is simple. Conditions for the gas-phase diffusion can be set by combining conditions known in the art.

The barrier film is etched and removed, and subsequently an antireflection film, such as a silicon nitride or titanium oxide film, may be formed on the surface of the second conductivity type semiconductor layer on the light-receiving side of the substrate by means of plasma CVD, atmospheric pressure CVD, spin coating or the like.

Next, a second conductivity type semiconductor layer that is formed on the rear surface of the semiconductor substrate is etched and removed. Furthermore, a rear electric field layer and a rear electrode are preferably formed on the rear surface by printing and burning an aluminum paste.

According to the present invention, it is preferred to form the front electrode which contact with the second conductivity type semiconductor layer at the convex portion of the surface of the resultant semiconductor substrate in step (c). The method for forming the front electrode is not particularly limited, and examples thereof include vapor deposition, CVD, EB, and printing/firing processes. The printing/firing process is particularly preferable because it uses a conductive paste to print and burn the front electrodes so as to extend over the top of the convex portions, thereby to simply and surely allow the front electrodes penetrate through the antireflection layer and contact the second conductivity type semiconductor layer in the vicinity of the top of the convex portions where the thickness of the coating film is small. Conditions for the printing/firing process can be appropriately set by combining materials and conditions known in the art.

In the case where the front electrodes are formed perpendicularly to linearly formed the convex portions or where the front electrodes are formed to extend over the convex portions of the semiconductor substrate having lattice-form convex and concave portions, it is desired to apply, before the formation of the front electrodes, SG liquid or the like onto the surface of the antireflection film by spin coating and then dry and fire the applied liquid so that forming a coating film that has a thickness continuously increasing from the convex portions to the concave portions is formed (FIG. 2). In this case, the front electrodes penetrate through the coating film and the antireflection film at the convex portions where the thickness of the coating film formed thereon is small, so as to contact the second conductivity type semiconductor layer at the firing of the front electrodes. However, the front electrodes cannot penetrate through the concave portions where the thickness of the coating film formed thereon is large. As a result, the front electrodes point-contact the second conductivity type semiconductor layer in the vicinity of the top of the convex portions. Since the contacted area can be made small, the recombination rate of minority carries is restrained to a small value so that the characteristics of the photoelectric conversion device can be improved.

Finally, the front electrodes are coated with solder to provide a completed photoelectric conversion device.

In the manufacturing method of the photoelectric conversion device of the present invention, the formation of the rear electric field layer, the rear electrode, the antireflection layer, and a protective layer may be further performed by a method known in the art to complete a photoelectric conversion device. The rear electric field layer prevents minority carriers that reached the rear surface from being recombined in the rear electrode, contributing to a rise in the efficiency. Any material and method usually used in the art that can realize this contribution may be used to form the rear electric field layer.

In the case where the photoelectric conversion device of the present invention has a second conductivity type semiconductor layer that is thin at convex portions thereof and thick at concave portions thereof, the semiconductor substrate has convex and concave portions formed on a surface thereof, as described above. It is particularly preferred that the convex portions are formed linearly at regular intervals since the second conductivity type semiconductor layer can be formed thin at portions other than the vicinity of the bottoms of the concave portions which become contacted areas with the front electrodes, so that the second conductivity type semiconductor layer can be formed into a thinner film on average, as will be described below. The pitch of the convex portions and the pitch of the concave are not particularly limited, and are, for example, about 1 to 3 mm in view of the width of front electrodes which will be described later. The difference of the elevation between the concave and convex portions is not particularly limited, and is, for example, about 0.05 to 0.1 mm.

The second conductivity type semiconductor layer in this case has a structure in which the layer becomes thinner as it goes farther from the area where the layer and the front electrodes contact each other, as described below. In other words, it is preferred that the layer has a thickness that becomes thinner from the concave portions to the convex portions of the semiconductor substrate. In the semiconductor substrate in which the grooves are continuously formed, it is preferred that the thickness of the second conductivity type semiconductor layer is smallest at the top of the stripe-formed convex portions between the respective grooves and becomes evenly thicker from the top to the bottom of the grooves. In the semiconductor substrate in which the convex portions are arranged at regular intervals or in a lattice form, it is preferred that the thickness of the second conductivity type semiconductor layer is smallest at the convex portions and becomes thicker from the convex portions to the concave portions.

According to the second embodiment of the manufacturing method of a photoelectric conversion device of the present invention, a film containing second conductivity type impurities is formed in step (a′), on a first conductivity type semiconductor substrate having convex and concave portions on a surface thereof so that the film becomes thicker from the convex portion to the concave portion. The film may be formed either by applying an appropriate coating solution for forming this film on the semiconductor substrate by spin coating, dip coating, spray coating or some other coating, and then drying the applied solution. In the case where the coating solution is applied onto the substrate surface having the convex and concave portions by spin coating, the solution remains easily in the concave portions. Therefore, the coating film can easily be formed so as to become continuously or gradually thicker from the convex portions to the concave portions of the semiconductor substrate.

An example of the coating solution is PSG liquid (liquid wherein a phosphorus source such as diphosphorus pentaoxide is blended with SG liquid). The film thickness of the coating film can be appropriately adjusted depending on the material of the coating film, the kind of impurities to be used. It is suitable that the film thickness is, for example, about 50 to 300 nm at the thickest portions and is, for example, about 0 to 50 nm at the thinnest portions.

In step (b′), second conductivity type impurities are implanted into the surface of the semiconductor substrate through the film which is heated to be previously formed, so as to form a second conductivity type semiconductor layer.

Since the second conductivity type impurities are implanted by diffusion thereof from the film which is previously formed on the semiconductor substrate and contains the impurity, the impurities are less implanted as the thickness of the film becomes smaller. For this reason, the second conductivity type semiconductor layer is formed thin. In other words, the second conductivity type semiconductor layer is formed in such a manner that the thickness of the layer is inclined become thinner from the concave portions to the convex portions of the semiconductor substrate surface.

Next, the film is etched and removed, and subsequently an antireflection film is formed on the surface of the second conductivity type semiconductor layer, which is a light-receiving face, by means of plasma CVD or the like. Furthermore, aluminum paste is printed on the rear surface and then fired to form a rear electric field layer and a rear electrode.

According to the present invention, it is preferred to form a front electrode which linearly contact the second conductivity type semiconductor layer at the concave portion of the surface of the resultant semiconductor substrate in step (c′). The method for forming the front electrode is not particularly limited, and examples thereof include vapor deposition, CVD, EB, and printing/firing processes. The printing/firing process is particularly preferable because it use a conductive paste to print and burn the front electrodes so as to extend over the bottom of the concave portions, thereby to simply and surely allow the front electrodes penetrate through the antireflection layer in the bottoms of the concave portions of the second conductivity type semiconductor layer, wherein the film thickness is large, so as to contact the second conductivity type semiconductor layer. Conditions for the printing/firing process can be appropriately set by combining materials and conditions known in the art.

Finally, the front electrodes are coated with solder, so as to give a completed photoelectric conversion device.

### EXAMPLES

The photoelectric conversion device of the present invention and its manufacturing method are described in more detail by way of the following examples with reference to the attached drawings.

### Example 1

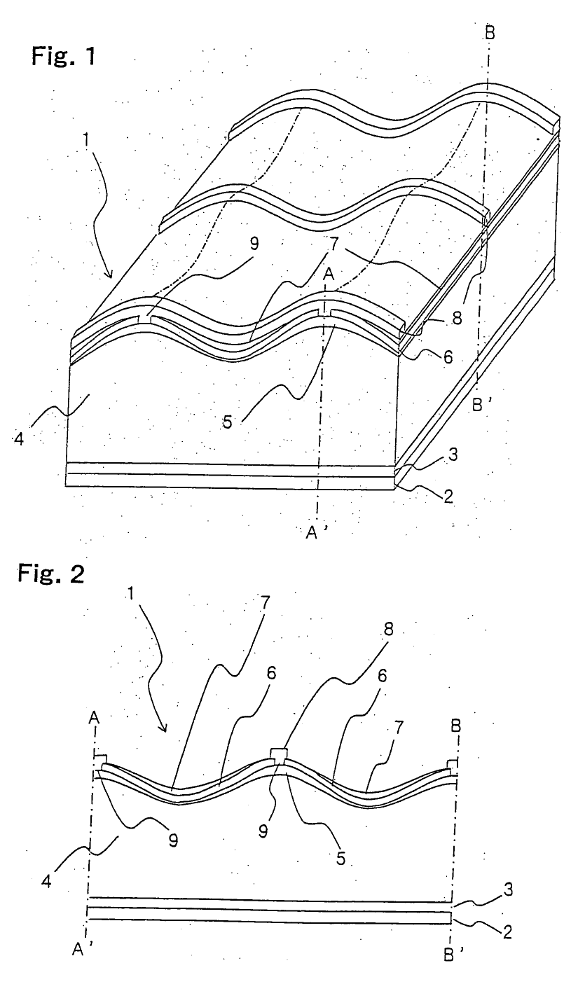

In a photoelectric conversion device 1, a P type semiconductor substrate is used. As illustrated in FIGS. 1 and 2, the photoelectric conversion devices 1 has a P type semiconductor substrate 4 of a first conductivity type, an N type semiconductor layer 5 of a second conductivity type which is formed on the surface of the P type semiconductor substrate 4, an antireflection layer 6 and a coating film 7 which are formed on the layer 5, and a rear electric field layer 3 which is formed a rear surface of the P type semiconductor substrate 4. The device 1 further includes a plurality of linear front electrodes 8 extending in one direction on the light-receiving surface of the substrate 4, and a rear electrode 2 formed on the rear surface of the substrate 4.

The surface of the P type semiconductor substrate has convex and concave portions in a lattice form. The thickness of the N type semiconductor layer is largest at the top of the convex portions, and becomes continuously thinner almost radially from the top of the convex portions to the concave portions. The coating film 7 is formed so as to be thick at the concave portions and thin at the convex portions of the substrate surface. The front electrodes 8 partially contact the N type semiconductor layer 5 at contacted areas 9 located on upper portions of the convex portions of the P type semiconductor substrate.

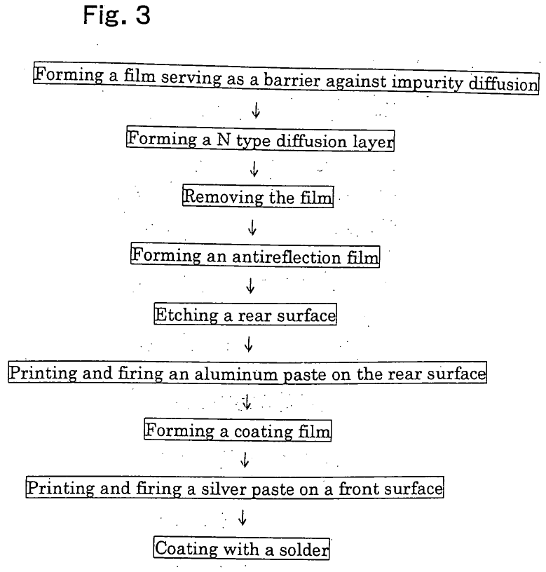

The photoelectric conversion device 1 can be formed in accordance with a process shown in a flow chart of FIG. 3.

First, SG liquid is applied by spin coating onto a P type semiconductor substrate (thickness: about 300 μm at the thickest portions, and about 200 μm at the thinnest portions) in which convex portions having even sizes are arranged in a lattice form so as to be positioned at regular intervals (pitch: 2 mm) so that a coating film serving as a barrier against impurity diffusion is formed. In this way, the coating film is formed so as to be thinnest at the top of the convex portions and become continuously thicker almost radially from the top of the convex portions to the concave portions. The film thickness of the coating film is about 250 nm at the thickest portions and about 20 nm at the thinnest portions.

Next, N type impurities are thermally diffused into the P type semiconductor substrate in the state, with the coating film is formed on the substrate that the N type semiconductor layer is formed. The thickness of the N type semiconductor layer is thickest at the top of the convex portions and becomes continuously thinner almost radially from the top of the convex portion to the concave portions. Here, phosphorus was diffused at 850° C. In this example, the diffusion coefficients of phosphorus in silicon and in the coating film are about 5×10⁻¹⁵ cm²/sec and about 3×10⁻¹⁵ cm²/sec respectively. Consequently, by the diffusion for ten minutes, the N type semiconductor layer is formed to have a thickness of about 0.1 μm at the thinnest portions and a thickness of 0.4 μm at the thickest portions.

Subsequently, the coating film is etched to be removed, and then a silicon nitride film having a substantially uniform thickness of about 700 nm is deposited on the surface of the N type semiconductor layer by plasma CVD to form an antireflection layer.

Furthermore, the rear surface of the substrate is etched to remove an N type semiconductor layer formed on the rear surface. Thereafter, an aluminum paste is printed on the rear surface and then burned to form a rear electric field layer of about 5 μm thickness and a rear electrode of about 50 μm thickness.

Next, SG liquid is applied onto the surface of the substrate by spin coating to form a coating film. At this time, the film thickness of the coating film is smallest at the top of the convex portions and becomes continuously thicker almost radially from the convex portions to the concave portions. The film thickness of the coating film is about 100 nm at the thickest portions and is about 5 nm at the thinnest portions.

Thereafter, a silver paste is printed on the coating film, and burned to form linear front electrodes that extend over the top of the convex portions. The width of the front electrodes is 100 μm, and the pitch of the front electrodes is 2 mm. The front electrodes fire through the antireflection film (that is, the front electrodes penetrate through the antireflection layer and the coating film in the step of printing and firing the electrodes) at the top of the convex portions, where the coating film is thinnest to contact the N type semiconductor layer.

Finally, the front electrodes are coated with solder to provide a photoelectric conversion device.

Characteristics of the photoelectric conversion device are evaluated. The results are shown in Table 1. As a comparative example provided and evaluated is a photoelectric conversion device substantially the same as the above-mentioned photoelectric conversion device except that the thickness of the semiconductor substrate is uniform even and the N type semiconductor layer is thinnest (0.1 μm) between the respective front electrodes and thickest (0.4 μm) under the front electrodes, as illustrated in FIG. 9.

TABLE 1

| | | | | Photoelectric |
|---|---|---|---|---|
| | Short-circuit | Open-circuit | | conversion |
| | current | voltage | | efficiency |
| | (mA/cm²) | (mV) | FF | (%) |
| Example 1 | 31.5 | 612 | 0.756 | 14.5 |
| Comparative | 30.3 | 610 | 0.757 | 14.0 |
| example | | | | |

It is understood from Table 1 that the photoelectric conversion device of Example 1 has a larger short-circuit current and a better photoelectric conversion efficiency than the comparative example. The film thickness of the N type semiconductor layer of the comparative example is large under the entire area where the linear front electrodes are formed, whereas the film thickness of the N type semiconductor layer of Example 1 is large in the vicinity of the top of the convex portions (the contacted area of the front electrodes and the second conductivity type semiconductor layer). Therefore, the photoelectric conversion device of Example 1 has a second conductivity type semiconductor layer, that is thinner than that of the comparative example on average ( i.e., averaging the thickness of the device entirety). As a result, the sensitivity to short wavelengths is improved and a resistance loss of optically-generated carriers is made smaller. Since the contacted areas are in the form of points, the contacted area of the front electrodes and the second conductivity type semiconductor layer is small, whereby the recombination of carries caused by the contact of the two can be reduced.

The average sheet resistance of the N type semiconductor layer is 120 Ω/□ in the working example according to the invention and 90 Ω/□ in the comparative example.

### Example 2

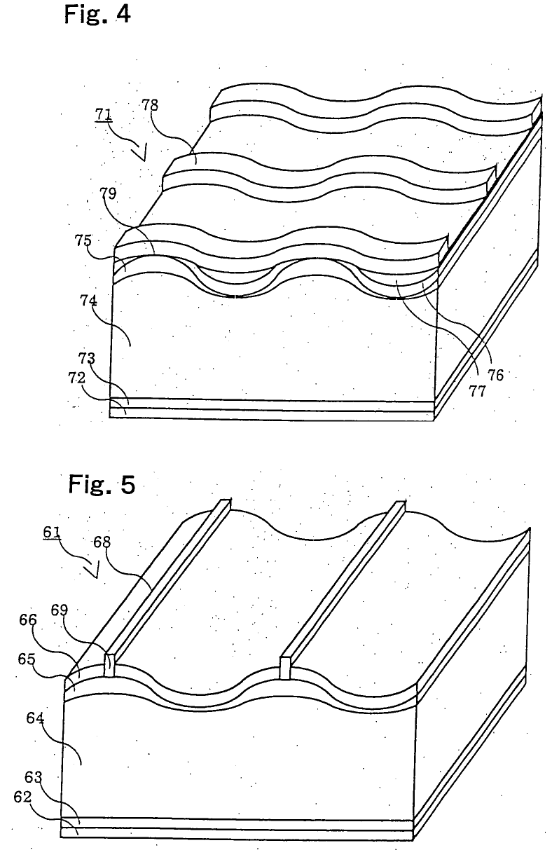

As illustrated in FIG. 4, produced is a photoelectric conversion device 71 which is the same as the device used in Example 1 except that a semiconductor substrate continuously provided with grooves having a pitch of 2 mm is used and front electrodes 78 were formed perpendicularly to the grooves. In FIG. 4, reference numbers 72 to 79 correspond to reference numbers 2 to 9 in FIG. 1, respectively.

A second conductivity type N type semiconductor layer 75 of the resultant photoelectric conversion device is thickest at the top of the convex portions of the substrate and becomes continuously thinner from the top of the convex portion to the bottom of the grooves. The thickness is 0.1 μm at the thinnest portions and is 0.4 μm at the thickest portions. The front electrodes are formed to cross the grooves at right angle, and point-contacted the N type semiconductor layer 75 at the top of the convex portions.

Characteristics of the photoelectric conversion device are evaluated. The results are shown in Table 2. As a comparative example provided and evaluated is a photoelectric conversion device substantially the same as the above-mentioned photoelectric conversion device except that the thickness of the semiconductor substrate is uniform and the front electrodes linearly contacted the thickest portions of the N type semiconductor layer, as illustrated in FIG. 9.

TABLE 2

| | | | | Photoelectric |
|---|---|---|---|---|
| | Short-circuit | Open-circuit | | conversion |
| | current | voltage | | efficiency |
| | (mA/cm²) | (mV) | FF | (%) |
| Example 2 | 30.6 | 612 | 0.757 | 14.2 |
| Comparative | 30.3 | 610 | 0.757 | 14.0 |
| example | | | | |

It is understood from Table 2 that the photoelectric conversion device of Example 2 has a larger short-circuit current and the open-circuit voltage and a better photoelectric conversion efficiency than the comparative example. That is, the contacted areas of the front electrodes are linear in the comparative example whereas the contacted areas of example 2 are in the form of points so that the contacted area of the front electrodes and the second conductivity type semiconductor layer is small, whereby the recombination of carries caused by the contact of the two can be reduced.

### Example 3

As illustrated in FIG. 5, produced is a same photoelectric conversion device 61 which is the same as the device used in Example 2 except that no coating film is formed at the formation of front electrodes 68 and the front electrodes 68 are formed in parallel to grooves along the top of the convex portions of the semiconductor substrate, as illustrated in FIG. 5. In FIG. 5, reference numbers 62 to 66 and 69 correspond to reference numbers 72 to 76 and 79, respectively.

A second conductivity type N type semiconductor layer 65 of the resultant photoelectric conversion device 61 is thickest at the top of the convex portions of the substrate and becomes continuously thinner from the top of the convex portions to the bottom of the grooves. The thickness is 0.1 μm at the thinnest portions and is 0.4 μm at the thickest portions. The front electrodes 68 are formed linearly along the top of the convex portion, and linearly contact the N type semiconductor layer 65 at the top of the convex portions. The surface of the substrate has convex and concave portions. Except these points, the photoelectric conversion device 61 is the same as the conventional device shown in FIG. 9.

As described above, a photoelectric conversion device which includes an N type semiconductor layer having a smallest thickness between respective front electrodes and having a largest thickness over the entire area located under the front electrodes is produced without performing cost-consuming steps such as laser-processing, photolithography, and multiple diffusion steps.

### Example 4

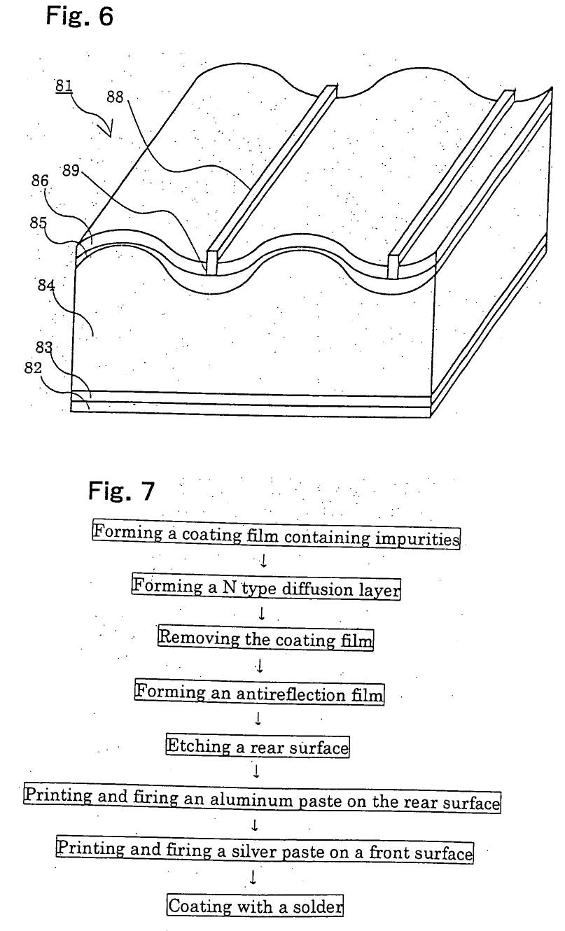

In a photoelectric conversion device 81, a P type semiconductor substrate is used. As illustrated in FIG. 6, the photoelectric conversion devices 81 has a P type semiconductor substrate 84 of a first conductivity type, an N type semiconductor layer 85 of a second conductivity type which is formed on the surface of the P type semiconductor substrate 84, an antireflection layer 86 which is formed on the layer 85, and a rear electric field layer 83 which is formed on the rear surface of the P type semiconductor substrate 84. The device further includes linear front electrodes 88 extending in one direction on the light-receiving surface of the P type semiconductor substrate 84, and a rear electrode 82 formed on the rear surface of the P type semiconductor substrate 84.

The surface of the P type semiconductor substrate has convex and concave portions having continuous grooves. The thickness of the N type semiconductor layer is smallest at the top of the convex portions, and continuously becomes larger from the top of the convex portions to the concave portions. The front electrodes 88 contact with the N type semiconductor layer 5 in contacted areas 89 which are in the bottom of the grooves of the P type semiconductor substrate.

This photoelectric conversion device 1 can be formed in accordance with a process shown in a flow chart of FIG. 7.

First, a coating solution containing N type impurities (such as PSG liquid) is applied by spin coating onto a P type semiconductor substrate (thickness: about 250 μm at the thickest portions, and about 200 μm at the thinnest portions) in which convex portions having substantially even sizes are arranged in a continuous stripe form so as to be positioned at regular intervals (pitch: 2 mm), thereby forming a coating film, serving as an impurity source. In this way, the coating film is formed so as to be thinnest at the top of the convex portions and become continuously thicker almost radially from the top of the convex portions to the concave portions. The film thickness of the coating film is about 100 nm at the thickest portions and about 5 nm at the thinnest portions.

Next, the coating film is dried and heated to diffuse the N type impurities from the coating film to the P type semiconductor substrate, thereby forming an N type semiconductor layer. The N type semiconductor layer is thinnest at the top of the convex portion and becomes continuously thicker from the top of the convex portions to the concave portions. The layer is formed to have a thickness of about 0.1 μm at the thinnest portions and a thickness of 0.4 μm at the thickest portions.

Subsequently, the coating film is etched and removed, and then a silicon nitride film having a substantially uniform thickness of about 700 nm is deposited on the surface of the N type semiconductor layer by plasma CVD to form an antireflection layer.

Furthermore, the rear surface is etched to remove an N type semiconductor layer formed on the rear surface of the substrate. Thereafter, an aluminum paste is printed on the rear surface and then burned to form a rear electric field layer of about 5 μm thickness and a rear electrode of about 50 μm thickness.

Thereafter, a silver paste is printed on the antireflection film, and burned to form linear front electrodes along the bottom of the grooves. The width of the front electrodes is 100 μm, and the pitch of the front electrodes is 2 mm. The front electrodes fire through the antireflection film (that is, the front electrodes penetrate through the antireflection layer in the step of printing and firing the electrodes) to contact the N type semiconductor layer.

Finally, the front electrodes are coated with solder to provide a photoelectric conversion device.

As described above, produced is a photoelectric conversion device which includes an N type semiconductor layer having a smallest thickness between respective front electrodes and having a largest thickness over the entire area located under the front electrodes without performing cost-consuming steps such as laser-processing, photolithography, and multiply diffusion steps.

According to the manufacturing method of the photoelectric conversion device of the present invention, simple steps such as a coating-film formation step and an impurity introduction step are performed. This allows a second conductivity type semiconductor layer having a desired film thickness gradient to be produced with reliability, without performing cost-consuming and troublesome laser step such as laser-processing, photolithography, and multiple diffusion step. It is therefore possible to reduce the manufacturing costs and further improve the yield.

1. In a photoelectric conversion device using a first conductivity type semiconductor substrate having convex and concave portions formed on its surface, the device being characterized in that it comprises at least:
a second conductivity type semiconductor layer formed on the surface of the first conductivity type semiconductor substrate;
a front electrode connected to the second conductivity type semiconductor layer; and
a rear electrode formed on the rear surface of the first conductivity type semiconductor substrate,
the second conductivity type semiconductor layer being at its partial area contact with the front electrode and becoming thinner as it goes farther from the contacted area.

2. The photoelectric conversion device according to claim 1, wherein the convex portions of the semiconductor substrate are arranged at given intervals and the second conductivity type semiconductor layer becomes thinner from the convex portions to the concave portions of the substrate.

3. The photoelectric conversion device according to claim 2, wherein each convex portion has the front electrode.

4. The photoelectric conversion device according to claim 1, wherein the convex portions of the semiconductor substrate are arranged at given intervals and the second conductivity type semiconductor layer becomes thicker from the top of the convex portions to the concave portions of the substrate.

5. The photoelectric conversion device according to claim 4, wherein each convex portion has the front electrode.

6. A method for manufacturing a photoelectric conversion device comprising the steps of:
(a) forming a film serving as a barrier against impurity diffusion on a semiconductor substrate having convex and concave portions formed on its surface in such a manner that the film becomes thicker from the convex portion to the concave portion; and
(b) implanting second conductivity type impurities into the semiconductor substrate through the film to form a second conductivity type semiconductor layer on the surface of the semiconductor substrate; and
(c) forming a front electrode that is in contact with the convex portion which constitutes a part of the semiconductor substrate surface.

7. (canceled)

8. A method for manufacturing a photoelectric conversion device comprising the steps of:
(a) forming a film containing second conductivity type impurities on a semiconductor substrate having convex and concave portions formed on its surface in such a manner that the film becomes thicker from the convex portion to the concave portion; and
(b) implanting second conductivity type impurities into the semiconductor substrate from the film to form a second conductivity type semiconductor layer on the surface of the semiconductor substrate; and
(c) forming a front electrode that is in contact with the concave portion which constitute a part of the semiconductor substrate surface.

9. (canceled)
